(19) United States
(12) Patent Application Publication
(10) Pub. No.: US 2019/0004349 A1
(43) Pub. Date: Jan. 3, 2019

(54) DISPLAY DEVICE

(71) Applicant: Ortus Technology Co., Ltd., Hino (JP)

(72) Inventor: Nobuyuki KOBAYASHI, Hino (JP)

(73) Assignee: Ortus Technology Co., Ltd., Hino (JP)

(21) Appl. No.: 16/124,897

(22) Filed: Sep. 7, 2018

Related U.S. Application Data
(63) Continuation of application No. PCT/JP2017/009020, filed on Mar. 7, 2017.

(30) Foreign Application Priority Data
Mar. 9, 2016 (JP) 2016-045521

(51) Int. Cl. G02F 1/1339; G02F 1/1347; G02F 1/1335; H01L 27/12

(52) U.S. Cl. CPC G02F 1/1339; G02F 1/13476; G02F 1/133528; G02F 1/133553; G02F 1/133512; H01L 27/1214; G02F 1/133514

(57) ABSTRACT

A display device includes: first and second display panels; and a spacer that bonds the first display panel and the second display panel together so as to leave a gap between the first and second display panels. The spacer is formed so as to surround a central portion of the first display panel, and has a slit.

### CROSS-REFERENCE TO RELATED APPLICATIONS

This application is a Continuation Application of PCT Application No. PCT/JP2017/009020, filed Mar. 7, 2017, and based upon and claiming the benefit of priority from Japanese Patent Application No. 2016-045521, filed Mar. 9, 2016, the entire contents of all of which are incorporated herein by reference.

### BACKGROUND OF THE INVENTION

### 1. Field of the Invention

The present invention relates generally to a display device.

### 2. Description of the Related Art

Various images can be displayed by constructing a display device by overlapping two types of display panels (for example, liquid crystal display panels) capable of displaying different images (Japanese Patent No. 5640178).

### BRIEF SUMMARY OF THE INVENTION

According to an aspect of the present invention, there is provided a display device comprising:

first and second display panels; and

a spacer that bonds the first display panel and the second display panel together so as to leave a gap between the first and second display panels,

wherein the spacer is formed so as to surround a central portion of the first display panel, and has a slit.

### BRIEF DESCRIPTION OF THE SEVERAL VIEWS OF THE DRAWINGS

FIG. 1 is a cross-sectional view of a liquid crystal display unit according to the present embodiment.

FIG. 2 is a perspective view of the liquid crystal display device according to the present embodiment.

FIG. 3 is a cross-sectional view of the liquid crystal display device taken along line A-A′ of FIG. 2.

FIG. 4 is a perspective view of a lower case.

FIG. 5 is a perspective view of an upper case.

FIG. 6 is a perspective view of a backlight and a liquid crystal display unit.

FIG. 7 is a plan view and a cross-sectional view of a spacer.

FIG. 8 is a plan view and a cross-sectional view of a spacer according to a modification.

### DETAILED DESCRIPTION OF THE INVENTION

A description will now be given of the embodiments with reference to the accompanying drawings. It should be noted that the drawings are schematic or conceptual, and the dimensions and scales of the drawings are not necessarily the same as the actual products. Where the same portion is depicted in different drawings, the dimensions and scale of one drawing may be different from those of another. Several embodiments described below merely show exemplary apparatuses and methods that implement the technical ideas of the present invention. The technical ideas are not limited by the element shapes, structures, arrangements, etc. described below. In the description below, structural elements having substantially the same functions and configurations will be denoted by the same reference symbols, and a repetitive description of such elements will be given only where necessary.

### [1] Configuration of Liquid Crystal Display 10

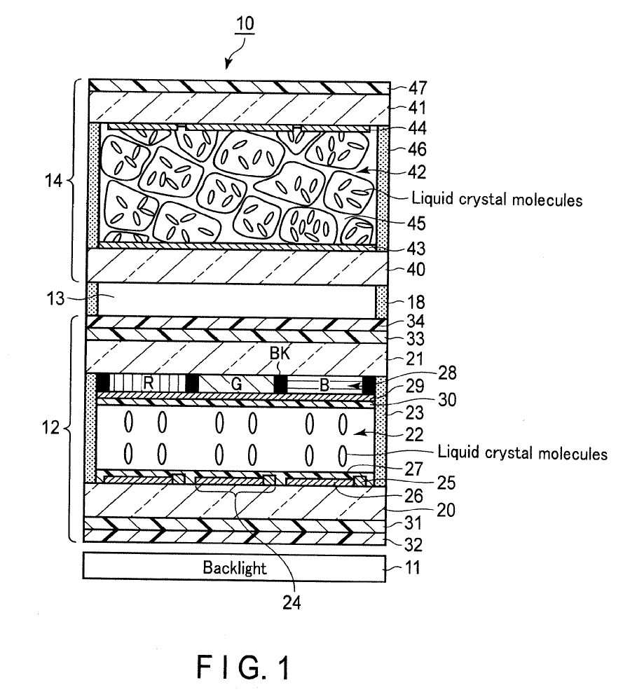

The liquid crystal display unit 10 of the present embodiment is a liquid crystal display panel used for, for example, an electronic wrist watch. FIG. 1 is a cross-sectional view of a liquid crystal display unit 10 according to the present embodiment. The liquid crystal display unit 10 includes a first liquid crystal display panel 12 and a second liquid crystal display panel 14, and the first liquid crystal display panel 12 and the second liquid crystal display panel 14 are laminated via a transparent member (for example, air layer) 13.

The first liquid crystal display panel 12 performs character display and image display (hereinafter referred to as information display) with a large amount of information and is capable of color display. The first liquid crystal display panel 12 is composed of a transmissive liquid crystal display panel with a color filter. That is, the first liquid crystal display panel 12 modulates light from a backlight 11 to display an image.

The second liquid crystal display panel 14 is of a pattern display type that performs character display and graphic display (hereinafter referred to as character display) with a small amount of information. The second liquid crystal display panel 14 can perform display of transparent state and a scattering state, namely, a monochrome display. Character display includes display of characters and figures with a small amount of information, and clock display (segment display), etc. The second liquid crystal display panel 14 is composed of, for example, a liquid crystal display panel selected from polymer dispersed liquid crystal (PDLC) and polymer network liquid crystal (PNLC). Since the second liquid crystal display panel 14 does not use a polarizer, absorption of the light intensity of the liquid crystal display panel itself can be greatly reduced, and a bright screen can be obtained. The second liquid crystal display panel 14 has visibility at the bottom of the panel and can be driven with less electric power.

As described above, in the liquid crystal display unit 10 of the present embodiment, the second liquid crystal display panel 14 performs character display (including clock display and standby display), and the first liquid crystal display panel 12 displays information having a larger amount of information than the character display performs a display.

The first liquid crystal display panel 12 and the second liquid crystal display panel 14 are laminated via a transparent member 13. The transparent member 13 contacts a lower substrate 40 of the second liquid crystal display panel 14, and the refractive index of the transparent member 13 is set to be different from the refractive index of the lower substrate 40. The transparent member 13 may be a transparent material that satisfies the above conditions, and may be a gas. In the present embodiment, the transparent member 13 is composed of, for example, an air layer 13. The air layer 13 is provided between the first liquid crystal display panel 12 and the second liquid crystal display panel 14 by a spacer (or sealing member) 18. By providing the air layer 13 between the first liquid crystal display panel 12 and the second liquid crystal display panel 14, the light incident on the second liquid crystal display panel 14 from the display surface side is reflected by a boundary face between the lower substrate 40 and the air layer 13. Consequently, bright display by the second liquid crystal display panel 14 can be realized, and the contrast of the liquid crystal display unit 10 can be improved.

A light source unit (backlight) 11 is disposed on a surface opposing the display surface of the liquid crystal display unit 10 to face the liquid crystal display unit 10. The backlight 11 is a surface light source. A direct-type or side-light type (edge-light type) LED backlight or electroluminescence (EL) backlight, for example, is used as the backlight 11.

(Configuration of First Liquid Crystal Display Panel 12)

Next, the configuration of the first liquid crystal display panel 12 will be described. For the first liquid crystal display panel 12, an active matrix system, in which active elements are arranged for each pixel, is used.

The first liquid crystal display panel 12 includes a TFT substrate 20 on which a thin film transistor (TFT) as an active element (switching element), and a pixel electrode, etc. are formed, a color filter substrate (CF substrate) 21 on which a color filter and a common electrode are formed and which is disposed opposite the TFT substrate 20, and a liquid crystal layer 22 held between the TFT substrate 20 and the CF substrate 21. Each of the TFT substrate 20 and the CF substrate 21 is composed of a transparent substrate (e.g., a glass substrate).

The liquid crystal layer 22 is composed of a liquid crystal material sealed by a sealing member 23 used for bonding the TFT substrate 20 and the CF substrate 21 together. In the liquid crystal material, the alignment of the liquid crystal molecules is manipulated according to an electric field applied between the TFT substrate 20 and the CF substrate 21, whereby the optical characteristics change. In the first liquid crystal display panel 12 of the present embodiment, for example, a VA mode using a vertical alignment (VA) type liquid crystal is used. That is, a negative type (N type) nematic liquid crystal is used as the liquid crystal layer 22, and the liquid crystal molecules are aligned substantially perpendicular to the substrate surface when no voltage is applied (no electric field) thereto. In the alignment of the liquid crystal molecules in the VA mode, the long axis (director) of the liquid crystal molecules is aligned in the vertical direction when no voltage is applied thereto, and the long axis of the liquid crystal molecules is inclined toward the horizontal direction at the time of voltage application (electric field application). In the liquid crystal mode other than the VA mode, a homogeneous mode or a twisted nematic (TN) mode can also be used. From the viewpoint of improving the contrast, the VA mode is more suitable.

On the TFT substrate 20, a switching element (TFT) 25 and a pixel electrode 26 are provided for each pixel 24. Also, on the TFT substrate 20, an alignment film 27 is provided so as to cover the TFT 25 and the pixel electrode 26. One display pixel (pixel) is composed of three sub-pixels having color filters of red (R), green (G), and blue (B). In the following description, it is assumed that a sub pixel is referred to as a pixel unless distinction between a display pixel and a sub pixel is particularly necessary. The TFT 25 is formed on the liquid crystal layer 22 side of the TFT substrate 20, and is a switching element that switches ON/OFF of the pixel 24.

The pixel electrode 26 is provided for each pixel 24, and is formed over the entire region of the pixel 24 corresponding thereto. The pixel electrode 26 is for applying a voltage to the liquid crystal layer 22 and is electrically coupled to one end of the current path of the TFT 25. The pixel electrode 26 is made of a transparent conductive film such as indium tin oxide (ITO). The alignment film 27 controls the alignment of liquid crystal molecules.

On or above the CF substrate 21, a color filter 28, a common electrode 29, and an alignment film 30 are provided. The color filter 28 is provided on the liquid crystal layer 22 side of the CF substrate 21 and is provided with coloring members of three colors of a red filter R, a green filter G, and a blue filter B. Each of the red filter R, the green filter G, and the blue filter B is disposed at a position facing the pixel electrode 26, and constitutes a sub pixel. A light shielding film (black matrix) BK for preventing color mixing is formed between the red filter R, the green filter G, and the blue filter B.

The common electrode 29 is provided on the liquid crystal layer 22 side of the color filter 28, and is formed in a planar shape over the entire display area. The common electrode 29 is made of a transparent conductive film such as ITO. The alignment film 30 forms a pair with the alignment film 27 and controls the alignment of the liquid crystal molecules. In the present embodiment, the alignment films 27 and 30 are formed in such a state that there is substantially no potential difference between the pixel electrode 26 and the common electrode 29, i.e., in a state where no electric field is applied between the pixel electrode 26 and the common electrode 29, and liquid crystal molecules are aligned in a direction substantially perpendicular to the substrate surface.

On the backlight 11 side of the TFT substrate 20, a retardation plate 31 and a polarizer 32 are provided. On the display surface side of the CF substrate 21, a retardation plate 33 and a polarizer 34 are provided. The polarizers 32 and 34 extract light having a vibration plane in one direction parallel to the transmission axis, i.e., light having a polarization state of linearly polarized light from light having a vibration plane in a random direction. The polarizers 32 and 34 are arranged so that the absorption axis and the transmission axis are orthogonal to each other in the plane.

The retardation plates 31 and 33 have refractive index anisotropy and are disposed so that the slow axis and the fast axis are orthogonal to each other in the plane. The retardation plates 31 and 33 have a function of providing a predetermined retardation (a phase difference of λ/4, where A is a wavelength of light transmitted therethrough) between light having a predetermined wavelength that passes through the slow axis and light having a predetermined wavelength that passes through the fast axis. That is, the retardation plates 31 and 33 are composed of λ/4 plates. The slow axes of the retardation plates 31 and 33 are set to approximately 45° with respect to the transmission axes of the polarizers 32 and 34, respectively.

It should be noted that the angle defining the polarizer and the retardation plate described above include an error that can realize a desired operation and an error caused by a manufacturing process. For example, the above-mentioned approximate 45° includes a range of 45°±5°. For example, being orthogonal described above is assumed to encompass a range of 90°±5°.

The first liquid crystal display panel 12 may be provided with an optical member for improving display characteristics on the uppermost layer thereof (a layer on the side opposite the liquid crystal layer 22 of the polarizer 34). In this case, the optical member comes into contact with the air layer 13.

(Configuration of Second Liquid Crystal Display Panel 14)

Next, the structure of a second liquid crystal display panel 14 will be described. The second liquid crystal display panel 14 includes a lower substrate 40 on which a common electrode is formed, an upper substrate 41 on which a display electrode is formed and which is disposed opposite the lower substrate 40, and a liquid crystal layer 42 held between the lower substrate 40 and the upper substrate 41. The positional relationship between the common electrode and the display electrode may be reversed. The surface of the upper substrate 41 opposite the liquid crystal layer 42 corresponds to the display surface of the liquid crystal display unit 10. The lower substrate 40 and the upper substrate 41 are each made of a transparent substrate (e.g., a glass substrate).

On the lower substrate 40, a common electrode 43 is provided. The common electrode 43 is formed in a planar shape over the entire display area. On the upper substrate 41, a plurality of display electrodes 44 are provided. The plurality of display electrodes 44 are processed into shapes corresponding to characters that can be displayed by the second liquid crystal display panel 14. The common electrode 43 and the display electrode 44 are each made of a transparent conductive film such as indium tin oxide (ITO). On the display surface side of the upper substrate 41, an ultraviolet (UV) cut film 47 is provided.

The liquid crystal layer 42 is sealed with a sealing member 46 for bonding the lower substrate 40 and the upper substrate 41 together. As described above, the liquid crystal layer 42 is formed of a polymer dispersed liquid crystal (PDLC) or a polymer network liquid crystal (PNLC). PNLC has a structure in which a liquid crystal material is dispersed in a polymer network 45, and the liquid crystal material in the polymer network 45 has a continuous phase. PDLC has a structure in which a liquid crystal is dispersed by a polymer; namely, a liquid crystal is phase separated in a polymer. As a polymer layer, a photocurable resin can be used. For example, in PNLC, ultraviolet rays are applied to a solution obtained by mixing a liquid crystal material with a photopolymerizable polymer precursor (monomer) to polymerize the monomer, thereby forming a polymer, and the liquid crystal material is dispersed in the network of the polymer.

As the liquid crystal material of the liquid crystal layer 42, a positive type (P type) nematic liquid crystal is used. That is, the long axes (directors) of the liquid crystal molecules are randomly aligned when no voltage is applied thereto (no electric field is applied thereto), and the directors of the liquid crystal molecules are aligned almost perpendicular to the substrate surface at the time of voltage application (electric field application).

The second liquid crystal display panel 14 may be provided with an optical member for improving display characteristics in the lowermost layer (a layer on the opposite side of the liquid crystal layer 42 of the lower substrate 40). In this case, the optical member comes into contact with the air layer 13.

### [2] Configuration of Liquid Crystal Display Device 50

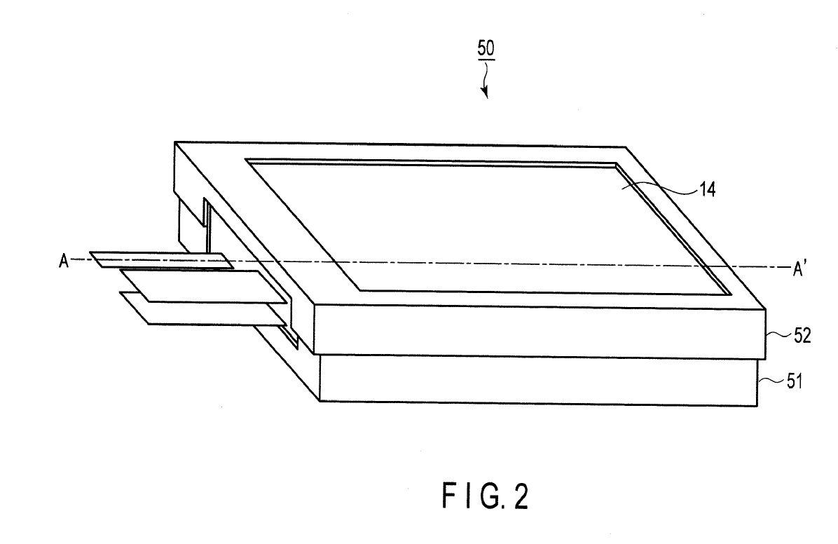

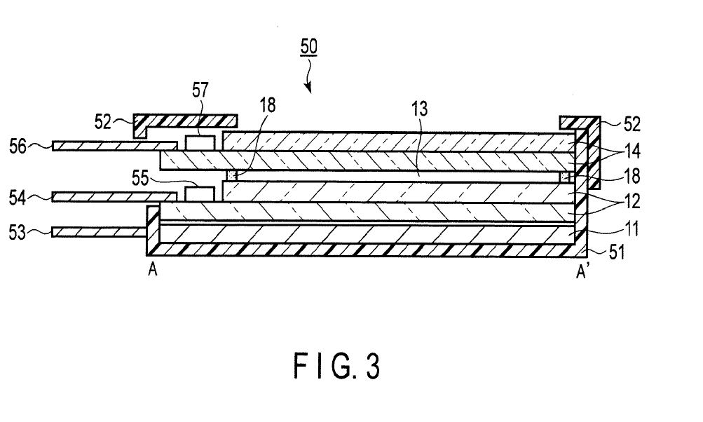

Next, the configuration of the liquid crystal display device 50 including the liquid crystal display unit 10 shown in FIG. 1 will be described. FIG. 2 is a perspective view of the liquid crystal display device 50 according to the present embodiment. FIG. 3 is a cross-sectional view of the liquid crystal display device 50 taken along line A-A′ of FIG. 2.

The thickness of the liquid crystal layer is sufficiently thin as compared with the thickness of the upper and lower transparent substrates between which the liquid crystal layer is sandwiched. Therefore, in order to simplify the drawing, in the cross-sectional view of FIG. 3, the first liquid crystal display panel 12 is represented by only the upper and lower transparent substrates 20 and 21, and similarly, the second liquid crystal display panel 14 is represented by only the upper and lower transparent substrates 40 and 41.

A lower case 51 accommodates the backlight 11, the first liquid crystal display panel 12, and the second liquid crystal display panel 14 in order from the bottom. In the lower case 51, a support member for fixing each of the backlight 11, the first liquid crystal display panel 12, and the second liquid crystal display panel 14 at a predetermined position (level) may be disposed.

An upper case 52 covers the lower case 51 and is fixed to the lower case 51. The upper case 52 has an opening through which light for displaying an image passes. The second liquid crystal display panel 14 is exposed from the opening of the upper case 52.

As a method for fixing the lower case 51 and the upper case 52, for example, a plurality of protrusions (not shown) are provided on the lower case 51, and a plurality of openings or a plurality of recesses (not shown) are provided in the upper case 52. One of the openings in the upper case 52 is disposed at a position corresponding to one protrusion of the lower case 51. The opening in the upper case 52 has the same size as the protrusion of the lower case 51. The size of one opening in the upper case 52 and one protrusion of the lower case 51 is, for example, about 1 to 2 mm. For example, the plurality of protrusions of the lower case 51 are provided uniformly on the four sides of the lower case 51, and the plurality of openings in the upper case 52 are provided uniformly in the four sides of the upper case 52. Then, the projection of the lower case 51 and the opening of the upper case 52 are fitted, whereby the lower case 51 and the upper case 52 are fixed. The lower case 51 and the upper case 52 may be fixed using screws, etc.

Hereinafter, respective parts constituting the liquid crystal display unit 10 will be specifically described.

[2-1] Lower Case 51

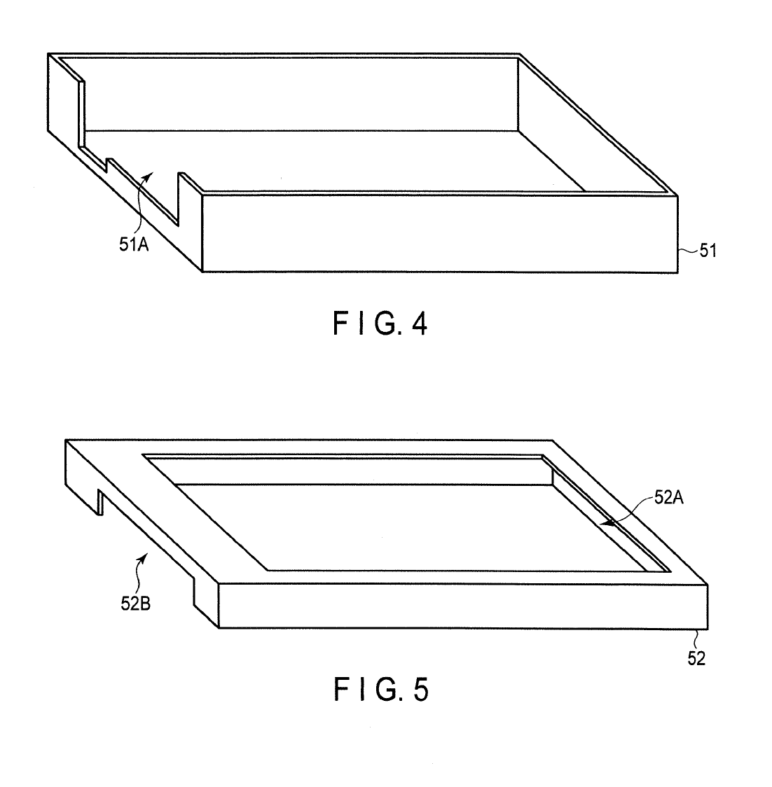

FIG. 4 is a perspective view of the lower case 51. The (planar) outer shape as viewed from above the lower case 51 is, for example, a quadrangle. The lower case 51 has a size and a depth capable of accommodating the backlight 11, the first liquid crystal display panel 12, and the second liquid crystal display panel 14. In other words, the lower case 51 has a bottom plate and four side plates and has a shape like a lid-free container.

On one side plate of the lower case 51, an opening 51A is provided for pulling out, to the outside, an interconnection portion coupled to the backlight 11, an interconnection portion coupled to the first liquid crystal display panel 12; and an interconnection portion coupled to the second liquid crystal display panel 14. The shape of the opening 51A is suitably designed according to the position and size of the interconnection portion. The lower case 51 is made of, for example, a resin.

[2-2] Upper Case 52

FIG. 5 is a perspective view of the upper case 52. The upper case 52 has an outer shape slightly larger than the lower case 51. That is, the inside size of the upper case 52 is substantially the same as the outside size of the lower case 51. An opening 52A through which light from the liquid crystal display unit 10 passes is formed in an upper portion of the upper case 52. The size of the opening 52A is set to be equal to or slightly larger than the display area of the liquid crystal display unit 10.

The upper case 52 has an upper frame having the opening 52A and four side plates. In one side plate of the upper case 52, an opening 52B is provided for pulling out, to the outside, the interconnection portion coupled to the backlight 11, the interconnection portion coupled to the first liquid crystal display panel 12, and the interconnection portion coupled to the second liquid crystal display panel 14. The shape of the opening 52B is suitably designed according to the position and size of the interconnection portion. The upper case 52 is made of, for example, a resin.

[2-3] Backlight 11, First Liquid Crystal Display Panel 12, Spacer 18, and Second Liquid Crystal Display Panel 14

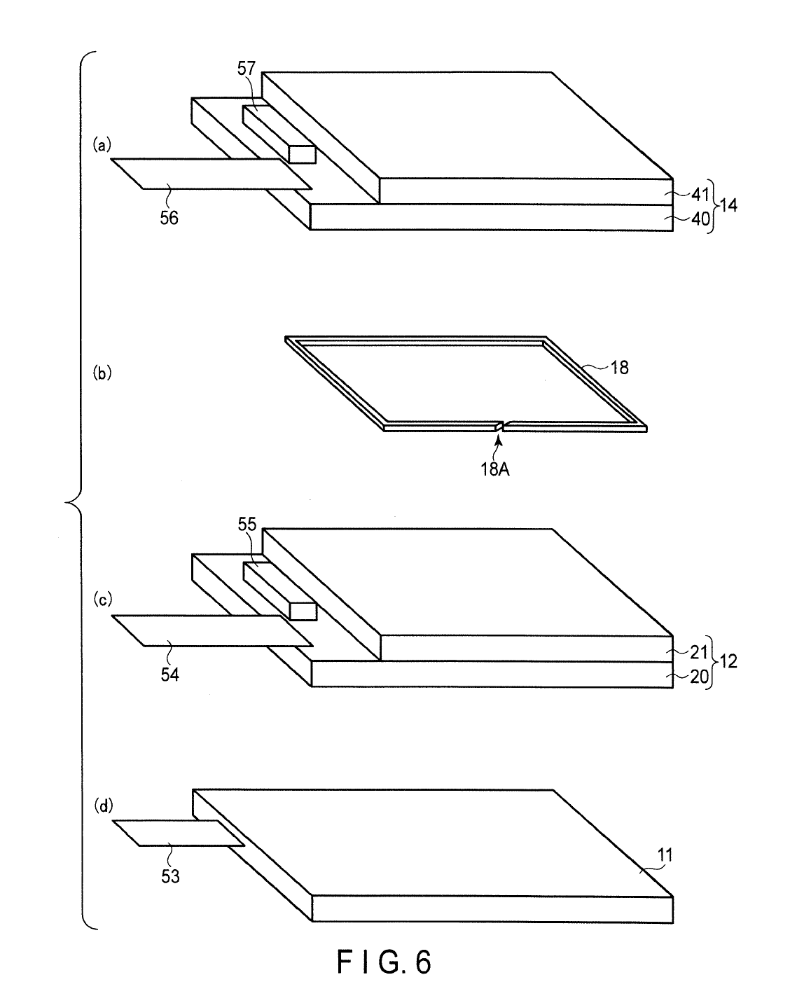

FIG. 6 is a perspective view of the backlight 11 and the liquid crystal display unit 10. FIG. 6 (a) is a perspective view of the second liquid crystal display panel 14, FIG. 6 (b) is a perspective view of the spacer 18, FIG. 6 (c) is a perspective view of the first liquid crystal display panel 12, and FIG. 6 (d) is a perspective view of the backlight 11. FIG. 6 shows the parts in order of lamination from the bottom to the top.

Although the backlight 11 is shown in a simplified form in FIG. 6 (d), it is composed of a surface light source as described above. The backlight 11 includes, for example, a laminate in which a reflective sheet, a light guide plate, a diffusion sheet, and a prism sheet (for example, two prism sheets) are laminated in this order, and an LED provided on a side surface of the laminate. The two prism sheets included in the backlight 11 are arranged such that the ridges of the prism rows are orthogonal to each other. An interconnection portion 53 is coupled to the backlight 11. The interconnection portion 53 is composed of, for example, a flexible printed circuit (FPC).

An interconnection portion 54 is coupled to the first liquid crystal display panel 12. The interconnection portion 54 is composed of, for example, an FPC. The first liquid crystal display panel 12 includes a driver 55. The driver 55 is provided, for example, on a TFT substrate 20 having a size larger than that of a CF substrate 21. The driver 55 drives the pixels 24 (specifically, the TFTs 25, the pixel electrodes 26, and the common electrode 29) by using various control signals and various voltages sent from the outside.

The spacer 18 is provided between the uppermost layer of the first liquid crystal display panel 12 and the lowermost layer of the second liquid crystal display panel 14. The outer shape of the spacer 18 is, for example, a quadrangle. The spacer 18 is formed in a line shape so as to surround the display region (the region where an image is displayed) of the liquid crystal display unit 10. Specifically, the outer shape of the spacer 18 is set so that the area surrounded by the inner side surface of the spacer 18 is larger than the display area of the liquid crystal display unit 10. The specific configuration of the spacer 18 will be described later.

An interconnection portion 56 is coupled to the second liquid crystal display panel 14. The interconnection portion 56 is composed of, for example, an FPC. The second liquid crystal display panel 14 includes a driver 57. The driver 57 is provided, for example, on the lower substrate 40 which is of a size larger than the upper substrate 41. The driver 57 drives the common electrode 43 and the display electrodes 44 by using various control signals and various voltages sent from the outside.

The interconnection portions 53, 54 and 56 pass through the opening 51A of the lower case 51 and the opening 52B of the upper case 52 and are pulled out of the liquid crystal display device 50. The interconnection portions 53, 54 and 56 are coupled to a power supply circuit and a control circuit, etc. provided outside the liquid crystal display device 50.

### [3] Specific Structure of Spacer 18

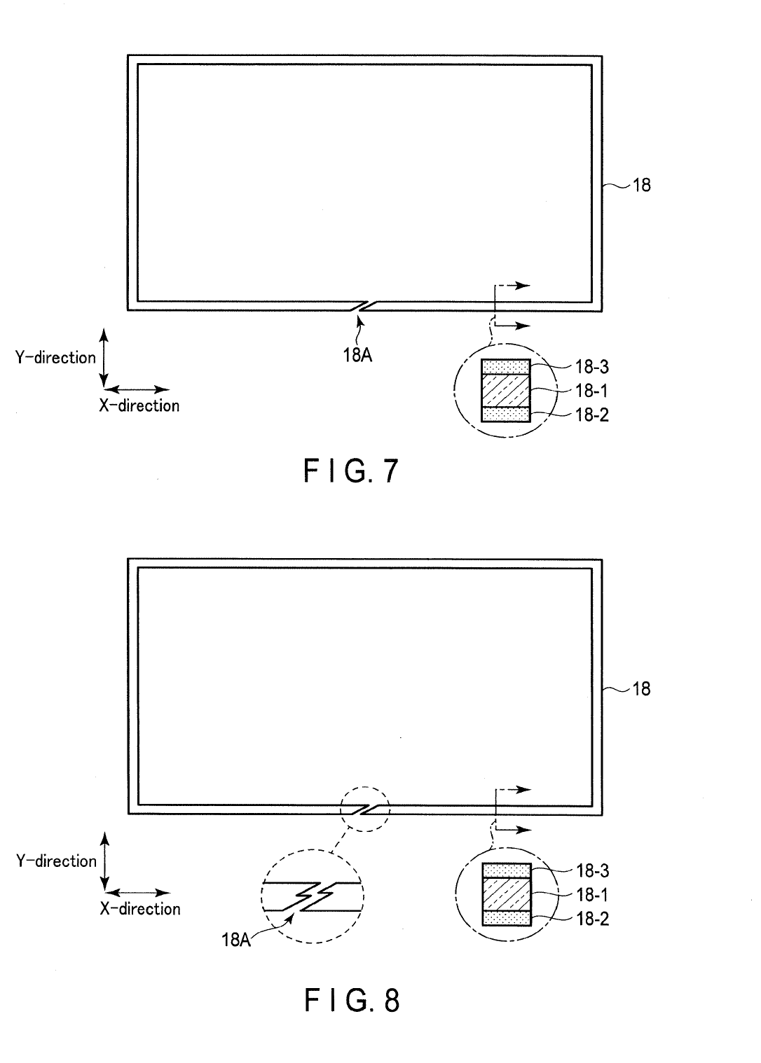

FIG. 7 is a plan view and a sectional view of the spacer 18. The spacer 18 has a quadrangle formed by four lines.

The spacer 18 has a function of leaving a gap between the first liquid crystal display panel 12 and the second liquid crystal display panel 14 and also a function of bonding the first liquid crystal display panel 12 and the second liquid crystal display panel 14 together. The region surrounded by the spacer 18 becomes the air layer 13 shown in FIG. 1.

The spacer 18 includes a base member 18-1, a first adhesive member 18-2 provided on the bottom surface of the base member 18-1, and a second adhesive member 18-3 provided on the upper surface of the base member 18-1. The first adhesive member 18-2 is bonded with the first liquid crystal display panel 12, and the second adhesive member 18-3 is bonded with the second liquid crystal display panel 14.

For the base member 18-1, for example, a transparent resin is used, and more specifically polyethylene terephthalate (PET) is used. Alternatively, for the substrate 18-1, a black color material (double-sided tape, resin, etc.) is used. By using the black color base member 18-1, it is possible to prevent light from being reflected by the spacer 18. For the adhesive members 18-2 and 18-3, for example, an acrylic adhesive material is used. The thickness of the spacer 18 is, for example, about 0.1 mm.

Here, the spacer 18 has a slit 18A in one of the four sides (lines). That is, the spacer 18 is not a perfect quadrangle but a part of it is divided by the slit 18A. The width of the slit 18A is desirably 0.2 mm or more and 0.5 mm or less. By narrowing the width of the slit 18A, it is possible to prevent foreign matters from entering from the slit 18A.

The slit 18A extends in an oblique direction that intersects with the Y-direction. The slit 18A serves as an entry port when air enters the air layer 13 and an outlet port when air is discharged from the air layer 13. With this configuration, it is possible to make the air pressure substantially the same between the inside and the outside of the spacer 18. As a result, even when the air pressure changes on the outside of the spacer 18, it is possible to prevent the thickness of the air layer 13 from changing; that is, it is possible to suppress a flexure (bending) of the first liquid crystal display panel 12 and/or the second liquid crystal display panel 14.

In addition, since the slit 18A extends in an oblique direction that intersects with the Y-direction, it is possible to prevent foreign matters from entering the air layer 13 via the slits 18A. The slit 18A is not limited to the one that extends obliquely, and may extend substantially in parallel with the Y-direction.

Furthermore, the slit 18A is provided on the side where the openings of the lower case 51 and the upper case 52 are not provided. That is, the slit 18A is provided so as to face a side plate which is different from the first side plate provided with the opening 51A in the lower case 51. With this configuration, even if a foreign matter enters the liquid crystal display device 50 via the openings of the lower case 51 and the upper case 52, it is possible to prevent foreign matter from entering the air layer 13 via the slit 18A.

In FIG. 7, since the side extending in the Y-direction on the left side of the spacer 18 faces the first side plate provided with the opening 51A in the lower case 51, it is sufficient for the slit 18A to be formed in any one of the three sides other than this side.

### [4] Modification of Spacer 18

FIG. 8 is a plan view and a sectional view of a spacer 18 according to a modification. The spacer 18 has a slit 18A.

The slit 18A has a zigzag shape while extending in an oblique direction that intersects with the Y-direction.

According to the modification, it is difficult for a foreign matter to pass through the slit 18A. With this configuration, it is possible to prevent the foreign matter from entering the air layer 13 via the slit 18A.

### [5] Effect of Present Embodiment

As described in detail above, in the present embodiment, the liquid crystal display device 50 includes the first liquid crystal display panel 12 and the second liquid crystal display panel 14; and the first liquid crystal display panel 12 and the second liquid crystal display panel 14 are laminated via the spacer 18. The spacer 18 bonds the first liquid crystal display panel 12 and the second liquid crystal display panel 14 together and also leaves a gap between the first liquid crystal display panel 12 and the second liquid crystal display panel 14 to provide the air layer 13. The spacer 18 has the slit 18A in a part thereof.

Therefore, according to the present embodiment, it is possible to make the air pressure substantially the same between the inside and the outside of the spacer 18. As a result, even when the air pressure changes on the outside of the spacer 18, it is possible to prevent the thickness of the air layer 13 from changing; that is, it is possible to suppress a flexure (bending) of the first liquid crystal display panel 12 and/or the second liquid crystal display panel 14. As a result, it is possible to prevent deterioration of the first liquid crystal display panel 12 and the second liquid crystal display panel 14.

In addition, the slit 18A is formed so as to extend in an oblique direction that intersects with the vertical direction (Y-direction) of the side (line). With this configuration, it is possible to prevent foreign matters from entering the air layer 13 via the slit 18A. As a result, it is possible to suppress degradation of the display characteristics of the liquid crystal display device 50.

In addition, both the information display by the first liquid crystal display panel 12 and the character display by the second liquid crystal display panel 14 are compatible, and the power consumption during the character display can be reduced. With this, even when the capacity of the power supply such as a primary battery is limited, the display time can be greatly lengthened.

The air layer 13 is provided between the first liquid crystal display panel 12 and the second liquid crystal display panel 14 so as to contact the lower substrate 40 of the second liquid crystal display panel 14. With this, reflected light that is reflected at a boundary face between the lower substrate 40 and the air layer 13 can be used for display, so that brighter display can be realized.

In the above embodiments, the first liquid crystal display panel 12 and the second liquid crystal display panel 14 may be constituted by display panels of types other than the above-mentioned examples. For the first liquid crystal display panel 12, it is also possible to use a semi-transmissive or reflective liquid crystal display device. For the first liquid crystal display panel 12, it is also possible to use an organic electroluminescence (EL) display device or other self-luminous display device. When a self-luminous display device is used as the first liquid crystal display panel 12, the backlight is omitted. For the second liquid crystal display panel 14, it is possible to use a transmissive display device (preferably without a color filter) other than a polymer dispersed liquid crystal display.

In the present specification, it is preferable that “(being) parallel” be taken to mean “completely parallel”. However, this is not necessarily required to mean “strictly parallel” but includes those that can be almost regarded as being substantially parallel in view of the effect of the present invention, and may include errors that may occur in the manufacturing process. Being “perpendicular or vertical” does not necessarily mean having to be strictly perpendicular or vertical, but may include those that can be substantially regarded as perpendicular or vertical in view of the effect of the present invention, and may include errors that may occur in the manufacturing process.

In this specification, a plate or a film is an expression that exemplifies members thereof, and is not limited to the configuration thereof. For example, the retardation plate is not limited to a plate-like member, and it may be a film or other member having the function described in the specification. In addition, the polarizer is not limited to a plate-like member, and may be a film or other member having the function described in the specification.

The present invention is not limited to the above-mentioned embodiments, and can be reduced to practice by modifying the constituent elements without departing from the spirit and scope of the invention. In addition, the above-described embodiments include inventions of various stages, and a variety of inventions can be derived by properly combining structural elements of one embodiment or by properly combining structural elements of different embodiments. For example, if the object of the invention is achieved and the advantages of the invention are attained even after some of the structural elements disclosed in connection with the embodiments are deleted, the structure made up of the resultant structural elements can be extracted as an invention.

What is claimed is:

1. A display device comprising:
first and second display panels; and
a spacer that bonds the first display panel and the second display panel together so as to leave a gap between the first and second display panels,
wherein the spacer is formed so as to surround a central portion of the first display panel, and has a slit.

2. The display device according to claim 1, wherein
the spacer includes an extending portion that extends in a first direction, and
the slit extends in an oblique direction relative to the first direction.

3. The display device according to claim 1, wherein the slit has a zigzag shape.

4. The display device according to claim 1, further comprising:
a first case that accommodates the first and second display panels; and
a second case that covers the first case from above,
wherein the first case comprises a first side plate having an opening, and
the slit is provided to face a side plate different from the first side plate in the first case.

5. The display device according to claim 1, wherein
the spacer comprises a base member, a first adhesive member provided under the base member, and a second adhesive member provided on the base member,
the first adhesive member is bonded with the first display panel, and
the second adhesive member is bonded with the second display panel.

6. The display device according to claim 1, wherein each of the first and second display panels is a liquid crystal display panel.

7. The display device according to claim 1, wherein
the first display panel is an active matrix liquid crystal display panel, and
the second display panel is a polymer dispersed or polymer network liquid crystal display panel.
